(19) United States
(12) Patent Application Publication
(10) Pub. No.: US 2025/0221018 A1
(43) Pub. Date: Jul. 3, 2025

(54) METHODS AND DEVICES THAT INCLUDE A GATE CONTACT THAT ABUTS A DIELECTRIC REGION THAT HAS A LOW-K DIELECTRIC

(71) Applicant: Taiwan Semiconductor Manufacturing Company, Ltd., Hsinchu (TW)

(72) Inventors: CHUN-YEN LIN, Hsinchu (TW); CHING-YU HUANG, Hsinchu (TW); WEI-CHENG TZENG, Taipei (TW); WEI-CHENG LIN, Taichung City (TW); JIANN-TYNG TZENG, Hsinchu (TW)

(21) Appl. No.: 18/398,951

(22) Filed: Dec. 28, 2023

(51) Int. Cl. H01L 27/085

(52) U.S. Cl. CPC H10D 84/82

(57) ABSTRACT

A semiconductor device including a first active area layer that extends in a first direction, a first metal over diffusion layer that extends in a second direction that is different than the first direction, the first metal over diffusion layer situated over the first active area layer, a first gate that extends in the second direction and over the first active area layer, a first gate end of the first gate that abuts a first dielectric region, and first low-k dielectric material situated in the first dielectric region.

### BACKGROUND

Typically, devices such as transistors are laid out adjacent one another in a plane, such as an x-y plane, of a semiconductor device. In some devices, complementary transistors are situated adjacent one another, such that one transistor is a p-type transistor and the adjacent transistor is an n-type transistor. The complementary transistors include active areas, also referred to herein as oxide diffusion (OD) layers, separated in the x-direction or the y-direction and gate regions connected by a gate contact.

Stacked complementary field-effect transistors (CFETs), include one transistor type, such as a p-type transistor, stacked above another transistor type, such as an n-type transistor. Stacking the complementary transistors, scales the cell area by 50%, where the active area layers of the transistors are separated in the z-direction and the gate regions are connected by a gate contact. Also, interconnections of the stacked CFETs are in the z-direction. Often, stacked CFET devices are used in semiconductor devices that include backside routing or power rails.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a semiconductor device that includes a 2D CMG region that cuts gates to provide shortened gate ends, in accordance with some embodiments.

FIG. 2 is a diagram schematically illustrating dimensions of the semiconductor device, in accordance with some embodiments.

FIG. 3 is a diagram schematically illustrating a semiconductor device that includes a first semiconductor device and a second semiconductor device, in accordance with some embodiments.

FIG. 4 is a diagram schematically illustrating a cross-section of the semiconductor device of FIG. 3 taken along the line A-A, in accordance with some embodiments.

FIG. 5 is a diagram schematically illustrating a semiconductor device that includes a 2D CMG region situated at least partly in each of a first semiconductor device and a second semiconductor device, in accordance with some embodiments.

FIG. 6 is a diagram schematically illustrating a cross-section of the semiconductor device of FIG. 5 taken along the line B-B, in accordance with some embodiments.

FIG. 7 is a diagram schematically illustrating a semiconductor device that includes a 2D CMG region, in accordance with some embodiments.

FIG. 8 is a diagram schematically illustrating a cross-section of the semiconductor device of FIG. 7 taken along the line C-C, in accordance with some embodiments.

FIG. 9 is a diagram schematically illustrating a semiconductor device that includes a 2D CMG region that includes a low-k dielectric and a high-k dielectric, in accordance with some embodiments.

FIG. 10 is a diagram schematically illustrating a cross-section of the semiconductor device of FIG. 9 taken along the line D-D, in accordance with some embodiments.

FIG. 11 is a diagram schematically illustrating a semiconductor device that includes a 2D CMG region that includes a low-k dielectric and a high-k dielectric, in accordance with some embodiments.

FIG. 12 is a diagram schematically illustrating a table of the geometry of the semiconductor device of FIG. 11, in accordance with some embodiments.

FIG. 13 is a diagram schematically illustrating the semiconductor device with a CMG region pattern etched into the semiconductor device, in accordance with some embodiments.

FIG. 14 is a diagram schematically illustrating filling the CMG region pattern with the high-k dielectric, in accordance with some embodiments.

FIG. 15 is a diagram schematically illustrating filling the space with the low-k dielectric, in accordance with some embodiments.

FIG. 16 is a diagram schematically illustrating the n-type transistors from the front-side of the semiconductor device, in accordance with some embodiments.

FIG. 17 is a diagram schematically illustrating the p-type transistors from the back-side of the semiconductor device, in accordance with some embodiments.

FIG. 18 is a diagram schematically illustrating the n-type transistors from the front-side of the semiconductor device connected as a 2-input NAND gate, in accordance with some embodiments.

FIG. 19 is a diagram schematically illustrating the p-type transistors from the back-side of the semiconductor device that is connected as a 2-input NAND gate, in accordance with some embodiments.

FIG. 20 is a diagram schematically illustrating a method of manufacturing a semiconductor device, such as the semiconductor device of FIGS. 13-15, in accordance with some embodiments.

FIG. 21 is a block diagram schematically illustrating an example of a computer system configured to provide the semiconductor devices and methods of the current disclosure, in accordance with some embodiments.

FIG. 22 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Each of the transistors in the CFET structures includes an active region where a source, drain, and channel are formed. The channel is situated under a gate having a gate contact. The active region is also referred to as an OD layer. The active area layers of the complementary transistors can be separated in the x-direction or the y-direction or the z-direction.

Some CFET structures include active area merged cells that include active area layers with enlarged active area layer widths, which increase the effective device current capabilities of the active area merged cells. The active area layers of the active area merged cells have larger widths than the active area layers of single height cells. Also, the active area merged cells have larger cell heights, such as a 1.5× cell height or a double cell height. However, in an active area merged cell, the active area layer has a maximum width limitation that results in longer gates from the active area layer to a first cut metal gate (CMG) region, where a CMG region is also referred to herein as a dielectric region. This results in larger gate end capacitors from the gates to metal over diffusion (MD) layers. A second CMG region can be situated near the active area layer to provide minimum length gate ends from the active area layer to the second CMG region. But, with cell height scaling of the active area merged cell, minimum spacing requirements between the first CMG region and the second CMG region cannot be maintained. Instead, the second CMG region is removed, which leads to longer gate ends from the active area layer to the first CMG region and larger gate end capacitors in the scaled cell.

Disclosed embodiments provide semiconductor devices that minimize the length of gate ends that extend from an active area layer of a cell to a CMG region that is also referred to herein as a dielectric region of the cell. This reduces the gate end capacitance, such as the gate end capacitance from a gate to an MD layer. In some embodiments, the gate end capacitance includes a polycrystalline silicon (polysilicon) gate end capacitance. In some embodiments, the gate end capacitance is from a gate in one cell to an MD layer in the same cell. In some embodiments, the gate end capacitance is from a gate in one cell to an MD layer in another cell. In some embodiments, the gate end capacitance is from a gate in one cell to an active area layer in another cell.

Disclosed embodiments further provide a semiconductor device that includes a gate and a CMG region, also referred to as a dielectric region, that abuts and cuts the gate to provide a shortened gate end. The CMG region includes a first portion having a first width and a second portion having a second width that is greater than the first width, where the second portion abuts and cuts the gate at the shortened gate end. A low-k dielectric material is situated in the second portion of the CMG region, also referred to as the dielectric region. In some embodiments, the shortened gate end is a minimum length gate end. Also, throughout the current specification a CMG region is also referred to as a dielectric region.

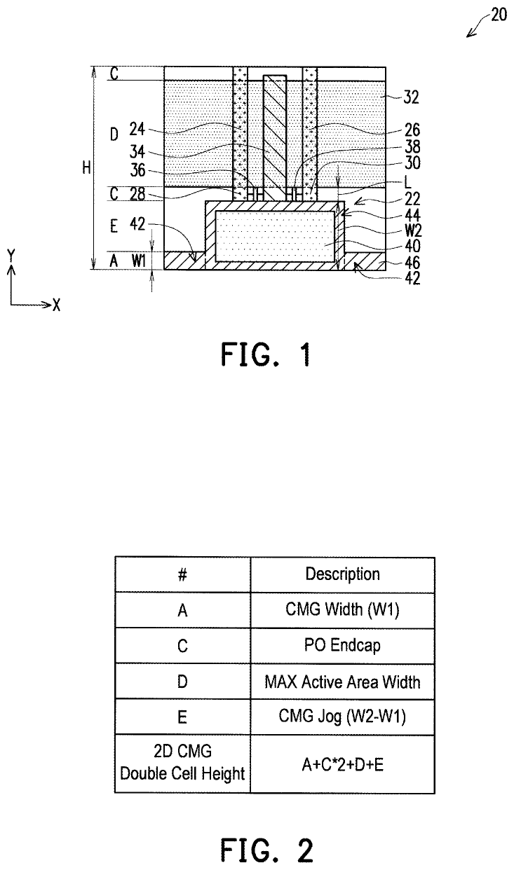

FIG. 1 is a diagram schematically illustrating a semiconductor device 20 that includes a 2D CMG region 22, also referred to as dielectric region 22, that abuts and cuts gates 24 and 26 to provide shortened gate ends 28 and 30, respectively, in accordance with some embodiments. In some embodiments, throughout the specification, gates, such as gates 24 and 26, include metal gate material. In some embodiments, throughout the specification, gates, such as gates 24 and 26, include polysilicon material. In some embodiments, throughout the specification, gates, such as gates 24 and 26, include any conductive material. In some embodiments, each of the shortened gate ends 28 and 30 is a minimum gate end length L.

The semiconductor device 20 includes the 2D CMG region 22, the gates 24 and 26, an active area layer 32, and an MD layer 34. The active area layer 32 extends in an x-direction and the MD layer 34 extends in a y-direction that is perpendicular to the x-direction. The MD layer 34 is situated over the active area layer 32. In other embodiments, the active area layer 32 extends in a first direction and the MD layer 34 extends in a second direction that is different than the first direction.

The gates 24 and 26 extend in the y-direction and over the active area layer 32. The 2D CMG region 22 cuts the gates 24 and 26 to provide the shortened gate ends 28 and 30. This results in smaller MD layer to gate end capacitances 36 and 38. The 2D CMG region 22 includes a low-k dielectric material 40.

The 2D CMG region 22 includes first portions 42 that have a first width W1 and a second portion 44 that has a second width W2 that is greater than the first width W1. The second portion 44 cuts the gates 24 and 26 to provide the shortened gate ends 28 and 30. The low-k dielectric material 40 is situated in the second portion 44 of the 2D CMG region 22.

The 2D CMG region 22 includes the low-k dielectric material 40 inside high-k dielectric material 46. In some embodiments, low-k dielectrics are dielectrics that have a dielectric constant, or k-value, that is lower than that of silicon dioxide (SiO2), k<3.9. In some embodiments, high-k dielectrics are dielectrics that have a dielectric constant, or k-value, that is higher than that of SiO2, k>3.9.

FIG. 2 is a diagram schematically illustrating dimensions of the semiconductor device 20, in accordance with some embodiments. The height H of the semiconductor device 20 includes the CMG width (W1) A, two gate endcaps C, a maximum active area width (Max active area width) D, and the CMG jog (W2−W1) E. The height H of the semiconductor device 20 with the 2D CMG region 22 is A+(C*2)+D+E.

FIG. 3 is a diagram schematically illustrating a semiconductor device 50 that includes a first semiconductor device 52 and a second semiconductor device 54, in accordance with some embodiments. The first semiconductor device 52 is a CFET that includes one type of active area layer/transistor situated, in the z-direction, above another type of active area layer/transistor, and the second semiconductor device 54 is a CFET that includes one type of active area layer/transistor situated, in the z-direction, above another type of active area layer/transistor. The first semiconductor device 52 is separated, in the y-direction, from the second semiconductor device 54. In some embodiments, each of the transistors in the first semiconductor device 52 and each of the transistors in the second semiconductor device 54 is like the semiconductor device 20 of FIG. 1.

The top transistor in the first semiconductor device 52 and the top transistor in the second semiconductor device 54 each include a 2D CMG region 22, gates 24 and 26, an active area layer 32, and MD layers 34. The active area layer 32 of the second semiconductor device 54 is separated, in the y-direction, from the active area layer 32 of the first semiconductor device 52. The active area layer 32 extends in the x-direction and the MD layers 34 extend in the y-direction that is perpendicular to the x-direction. Also, the MD layers 34 are situated over the active area layer 32, and the gates 24 and 26 extend in the y-direction over the active area layer 32. The 2D CMG region 22 extends in the z-direction and cuts the gates 24 and 26 to provide the shortened gate ends 28 and 30, respectively, which results in smaller MD layer to gate end capacitances and smaller active area layer to gate end capacitances, within each of the semiconductor devices 52 or 54 and from one of the semiconductor devices 52 and 54 to the other one of the semiconductor devices 52 and 54.

The 2D CMG region 22 includes a low-k dielectric material 40 and a high-k dielectric material 46. The 2D CMG region 22 includes first portions 42 that have a first width W1 and a second portion 44 that has a second width W2 that is greater than the first width W1. The second portion 44 cuts the gates 24 and 26 to provide the shortened gate ends 28 and 30. The low-k dielectric material 40 is situated in the second portion 44 of the 2D CMG region 22 and inside the high-k dielectric material 46.

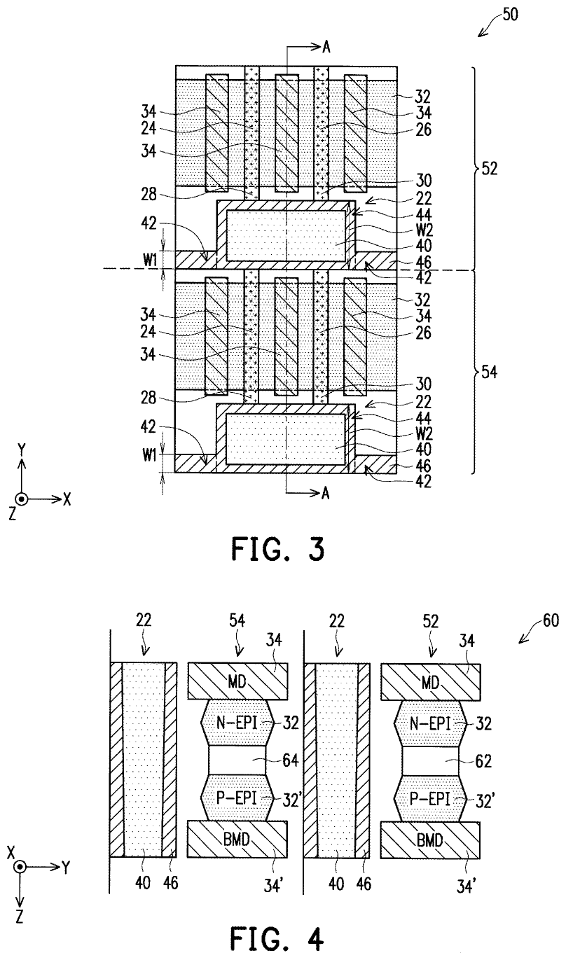

FIG. 4 is a diagram schematically illustrating a cross-section 60 of the semiconductor device 50 of FIG. 3 taken along the line A-A, in accordance with some embodiments. The cross-section 60 includes the first semiconductor device 52 and the second semiconductor device 54.

The first semiconductor device 52 includes the MD layer 34 situated on the active area layer 32 that is situated on an insulation layer 62. The insulation layer 62 is situated under the active area layer 32 and above the second active area layer 32′. The first semiconductor device 52 includes a bottom MD layer 34′ under the second active area layer 32′. The CMG region 22 extends in the z-direction and includes the high-k dielectric 46 and the low-k dielectric 40. The CMG region 22 cuts the gates 24 and 26. In some embodiments, the gates 24 and 26 extend over the active area layer 32 and the second active area layer 32′ and the CMG region 22 cuts the gates 24 and 26 that extend over the active area layer 32 and the second active area layer 32′. In some embodiments, the active area layer 32 is an n-type active area layer and the active area layer 32′ is a p-type active area layer. In some embodiments, the active area layer 32 is a p-type active area layer and the active area layer 32′ is an n-type active area layer.

The second semiconductor device 54 includes the MD layer 34 situated on the active area layer 32 that is situated on an insulation layer 64. The insulation layer 64 is situated under the active area layer 32 and above the second active area layer 32′. The second semiconductor device 54 includes a bottom MD layer 34′ under the second active area layer 32′. The CMG region 22 extends in the z-direction and includes the high-k dielectric 46 and the low-k dielectric 40. The CMG region 22 cuts the gates 24 and 26. In some embodiments, the gates 24 and 26 extend over the active area layer 32 and the second active area layer 32′ and the CMG region 22 cuts the gates 24 and 26 that extend over the active area layer 32 and the second active area layer 32′. In some embodiments, the active area layer 32 is an n-type active area layer and the active area layer 32′ is a p-type active area layer. In some embodiments, the active area layer 32 is a p-type active area layer and the active area layer 32′ is an n-type active area layer.

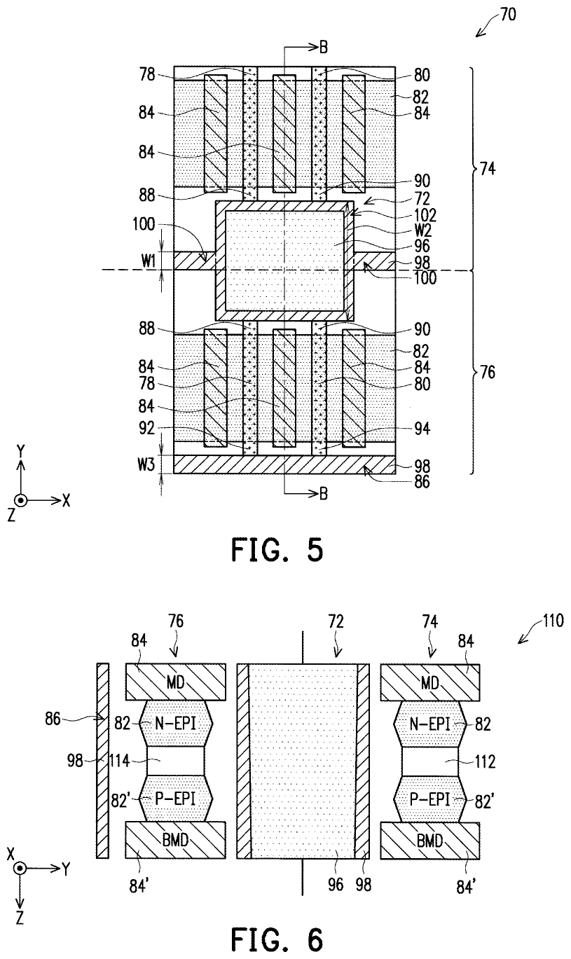

FIG. 5 is a diagram schematically illustrating a semiconductor device 70 that includes a 2D CMG region 72 situated at least partly in each of a first semiconductor device 74 and a second semiconductor device 76, in accordance with some embodiments. The first semiconductor device 74 is a CFET that includes one type of active area layer/transistor situated, in the z-direction, above another type of active area layer/transistor, and the second semiconductor device 76 is a CFET that includes one type of active area layer/transistor situated, in the z-direction, above another type of active area layer/transistor. The first semiconductor device 74 is separated, in the y-direction, from the second semiconductor device 76. In some embodiments, each of the transistors in the first semiconductor device 74 and each of the transistors in the second semiconductor device 76 is like the semiconductor device 20 of FIG. 1.

The top transistor in the first semiconductor device 74 and the top transistor in the second semiconductor device 76 each include gates 78 and 80, an active area layer 82, MD layers 84, and at least part of the 2D CMG region 72. Also, the top transistor in the second semiconductor device 76 includes a CMG region 86. The active area layer 82 of the second semiconductor device 76 is separated, in the y-direction, from the active area layer 82 of the first semiconductor device 74. The active area layer 82 extends in the x-direction and the MD layers 84 extend in the y-direction that is perpendicular to the x-direction. Also, the MD layers 84 are situated over the active area layer 82, and the gates 78 and 80 extend in the y-direction over the active area layer 82. The 2D CMG region 72 extends in the z-direction and cuts the gates 78 and 80 in each of the first semiconductor device 74 and the second semiconductor device 76 to provide the shortened gate ends 88 and 90. Also, the CMG region 86 extends in the z-direction and cuts the gates 78 and 80 in the second semiconductor device 76 to provide the shortened gate ends 92 and 94, respectively. This results in smaller MD layer to gate end capacitances and smaller active area layer to gate end capacitances, within each of the semiconductor devices 74 and 76 and from one of the semiconductor devices 74 and 76 to the other one of the semiconductor devices 74 and 76.

The 2D CMG region 72 includes a low-k dielectric material 96 and a high-k dielectric material 98. The 2D CMG region 72 includes first portions 100 that have a first width W1 and a second portion 102 that has a second width W2 that is greater than the first width W1. The second portion 102 cuts the gates 78 and 80 in each of the first semiconductor device 74 and the second semiconductor device 76 to provide the shortened gate ends 88 and 90. The low-k dielectric material 96 is situated in the second portion 102 of the 2D CMG region 72 and inside the high-k dielectric material 98. Also, the CMG region 86 has a third width W3 and includes the high-k dielectric material 98. In some embodiments, the first width W1 is the same as the third width W3.

FIG. 6 is a diagram schematically illustrating a cross-section 110 of the semiconductor device 70 of FIG. 5 taken along the line B-B, in accordance with some embodiments. The cross-section 110 includes the first semiconductor device 74 and the second semiconductor device 76.

The first semiconductor device 74 includes the MD layer 84 situated on the active area layer 82 that is situated on an insulation layer 112. The insulation layer 112 is situated under the active area layer 82 and above the second active area layer 82′. The first semiconductor device 74 includes a bottom MD layer 84′ under the second active area layer 82′. The CMG region 72 extends in the z-direction and includes the high-k dielectric 98 and the low-k dielectric 96. The CMG region 72 cuts the gates 78 and 80. In some embodiments, the gates 78 and 80 extend over the active area layer 82 and the second active area layer 82′ and the CMG region 72 cuts the gates 78 and 80 that extend over the active area layer 82 and the second active area layer 82′. In some embodiments, the active area layer 82 is an n-type active area layer and the active area layer 82′ is a p-type active area layer. In some embodiments, the active area layer 82 is a p-type active area layer and the active area layer 82′ is an n-type active area layer.

The second semiconductor device 76 includes the MD layer 84 situated on the active area layer 82 that is situated on an insulation layer 114. The insulation layer 114 is situated under the active area layer 82 and above the second active area layer 82′. The second semiconductor device 76 includes a bottom MD layer 84′ under the second active area layer 82′. The CMG region 72 extends in the z-direction and includes the high-k dielectric 98 and the low-k dielectric 96. The CMG region 72 cuts the gates 78 and 80. In some embodiments, the gates 78 and 80 extend over the active area layer 82 and the second active area layer 82′ and the CMG region 72 cuts the gates 78 and 80 that extend over the active area layer 82 and the second active area layer 82′.

Also, the second semiconductor device 76 includes the CMG region 86 that extends in the z-direction and cuts the gates 78 and 80 in the second semiconductor device 76 to provide the shortened gate ends 92 and 94, respectively. In some embodiments, the gates 78 and 80 extend over the active area layer 82 and the second active area layer 82′ and the CMG region 86 cuts the gates 78 and 80 that extend over the active area layer 82 and the second active area layer 82′. In some embodiments, the active area layer 82 is an n-type active area layer and the active area layer 82′ is a p-type active area layer. In some embodiments, the active area layer 82 is a p-type active area layer and the active area layer 82′ is an n-type active area layer.

FIG. 7 is a diagram schematically illustrating a semiconductor device 120 that includes a 2D CMG region 122, in accordance with some embodiments. The semiconductor device 120 is a CFET that includes two active area layers, one type of active area layer/transistor is situated, in the z-direction, above another type of active area layer/transistor. In some embodiments, each of the transistors in the semiconductor device 120 is like the semiconductor device 20 of FIG. 1.

The semiconductor device 120 includes the 2D CMG region 122, gates 124 and 126, and an active area layer 128. Also, the semiconductor device 120 can include one or more MD layers (not shown). The active area layer 128 extends in the x-direction and the gates 124 and 126 extend in the y-direction that is perpendicular to the x-direction. The gates 124 and 126 extend over, surrounding, the two active area layers in the CFET semiconductor device 120, including the active area layer 128.

The 2D CMG region 122 extends in the z-direction and cuts the gates 124 and 126 to provide the shortened gate ends 128 and 130, respectively, which results in smaller MD layer to gate end capacitances and smaller active area layer to gate end capacitances, within the semiconductor device 120 and from one semiconductor device, such as semiconductor device 120, to another semiconductor device.

The 2D CMG region 122 includes a high-k dielectric material 132. The 2D CMG region 122 includes first portions 134 that have a first width W1 and a second portion 136 that has a second width W2 that is greater than the first width W1. The second portion 136 cuts the gates 124 and 126 to provide the shortened gate ends 128 and 130, respectively.

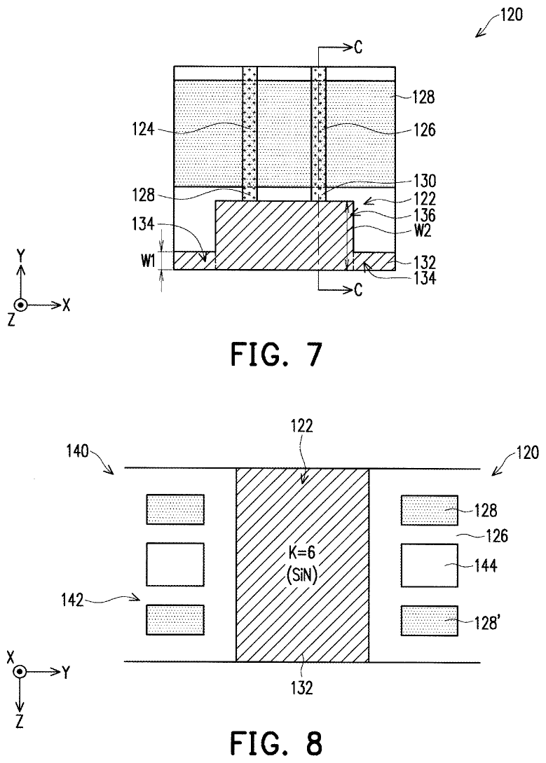

FIG. 8 is a diagram schematically illustrating a cross-section 140 of the semiconductor device 120 of FIG. 7 taken along the line C-C, in accordance with some embodiments. The cross-section 140 includes the semiconductor device 120 and part of a second device 142.

The semiconductor device 120 includes the gate 126 that surrounds the active area layer 128 and a second active area layer 128′. The gate 126 is situated on an insulation layer 144 that is under the active area layer 128 and above the second active area layer 128′. The CMG region 122 extends in the z-direction and includes the high-k dielectric 132. The CMG region 122 cuts the gate 126 that extends over the active area layer 128 and the second active area layer 128′. In some embodiments, the high-k dielectric 132 is silicon nitride (SiN) having a k-value of 6. In some embodiments, the active area layer 128 is an n-type active area layer and the active area layer 128′ is a p-type active area layer. In some embodiments, the active area layer 128 is a p-type active area layer and the active area layer 128′ is an n-type active area layer.

FIG. 9 is a diagram schematically illustrating a semiconductor device 150 that includes a 2D CMG region 152 that includes a low-k dielectric 154 and a high-k dielectric 156, in accordance with some embodiments. The semiconductor device 150 is a CFET that includes two active area layers, one type of active area layer/transistor is situated, in the z-direction, above another type of active area layer/transistor. In some embodiments, each of the transistors in the semiconductor device 150 is like the semiconductor device 20 of FIG. 1.

The semiconductor device 150 includes the 2D CMG region 152, gates 158 and 160, and an active area layer 162. Also, the semiconductor device 150 can include one or more MD layers (not shown). The active area layer 162 extends in the x-direction and the gates 158 and 160 extend in the y-direction that is perpendicular to the x-direction. The gates 158 and 160 extend over, surrounding, the two active area layers in the CFET semiconductor device 150, including the active area layer 162.

The 2D CMG region 152 extends in the z-direction and cuts the gates 158 and 160 to provide the shortened gate ends 164 and 166, respectively, which results in smaller MD layer to gate end capacitances and smaller active area layer to gate end capacitances, within the semiconductor device 150 and from one semiconductor device, such as semiconductor device 150, to another semiconductor device.

The 2D CMG region 152 includes the low-k dielectric 154 and the high-k dielectric 156 that surrounds the low-k dielectric 152 in at least the x-direction and the y-direction. The 2D CMG region 152 includes first portions 168 that have a first width W1 and a second portion 170 that has a second width W2 that is greater than the first width W1. The second portion 170 cuts the gates 158 and 160 to provide the shortened gate ends 164 and 166, respectively. The low-k dielectric 154 reduces the capacitance across the 2D CMG region 152, such as from one of the gates 158 and 160 to an MD layer or an active area layer in another device.

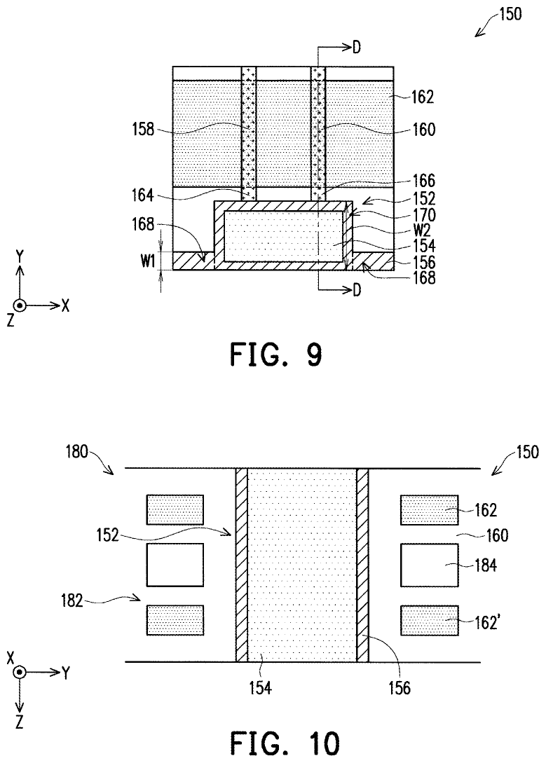

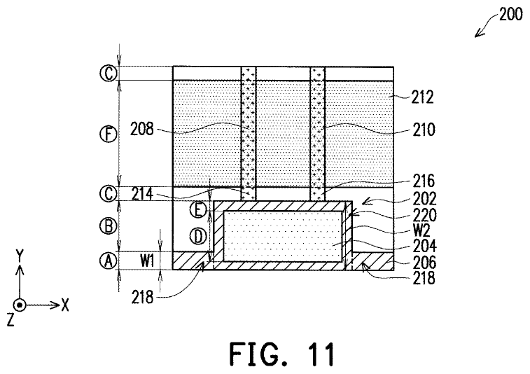

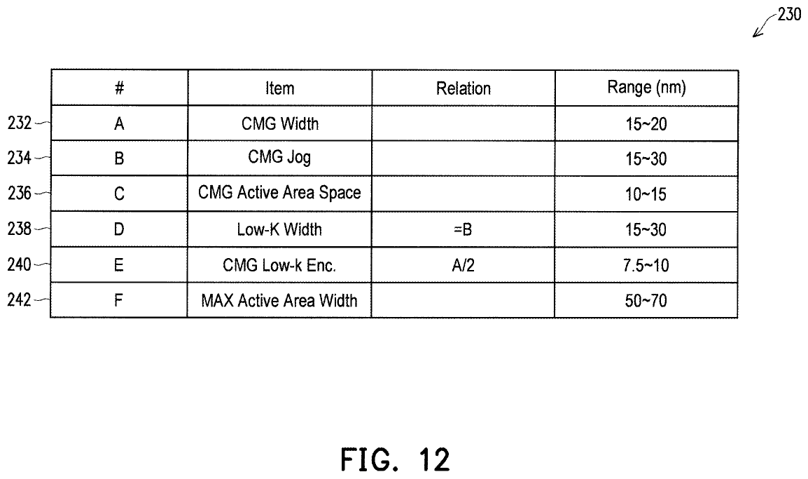

FIG. 10 is a diagram schematically illustrating a cross-section 180 of the semiconductor device 150 of FIG. 9 taken along the line D-D, in accordance with some embodiments. The cross-section 180 includes the semiconductor device 150 and part of a second device 182.

The semiconductor device 150 includes the gate 160 that surrounds the active area layer 162 and a second active area layer 162′. The gate 160 is situated on an insulation layer 184 that is under the active area layer 162 and above the second active area layer 162′. The CMG region 152 extends in the z-direction and includes the low-k dielectric 154 and the high-k dielectric 156 that surrounds the low-k dielectric 152 in at least the x-direction and the y-direction. The CMG region 152 cuts the gate 160 that extends over the active area layer 162 and the second active area layer 162′. In some embodiments, the high-k dielectric 156 has a k-value of 6. In some embodiments, the low-k dielectric 154 has a k-value of 0 to 3.9. In some embodiments, the active area layer 162 is an n-type active area layer and the active area layer 162′ is a p-type active area layer. In some embodiments, the active area layer 162 is a p-type active area layer and the active area layer 162′ is an n-type active area layer.

FIGS. 11 and 12 are diagrams schematically illustrating a semiconductor device 200 and geometry of the semiconductor device 200, in accordance with some embodiments. In some embodiments, a second semiconductor device is situated in the y-direction, above the semiconductor device 200. In some embodiments, a second semiconductor device is situated in the y-direction, below the semiconductor device 200.

FIG. 11 is a diagram schematically illustrating a semiconductor device 200 that includes a 2D CMG region 202 that includes a low-k dielectric 204 and a high-k dielectric 206, in accordance with some embodiments. In some embodiments, the semiconductor device 200 is a CFET that includes two active area layers, one type of active area layer/transistor is situated in the z-direction, above another type of active area layer/transistor. In some embodiments, the semiconductor device 200 is like the semiconductor device 20 of FIG. 1. In some embodiments, the semiconductor device 200 is like the semiconductor device 150 of FIG. 9.

The semiconductor device 200 includes the 2D CMG region 202, gates 208 and 210, and an active area layer 212. Also, the semiconductor device 200 can include one or more MD layers (not shown). The active area layer 212 extends in the x-direction and the gates 208 and 210 extend in the y-direction that is perpendicular to the x-direction.

The 2D CMG region 202 extends in the z-direction and cuts the gates 208 and 210 to provide the shortened gate ends 214 and 216, respectively, which results in smaller MD layer to gate end capacitances and smaller active area layer to gate end capacitances, within the semiconductor device 200 and from one semiconductor device, such as the semiconductor device 200, to another semiconductor device.

The 2D CMG region 202 includes the low-k dielectric 204 and the high-k dielectric 206 that surrounds the low-k dielectric 204 in at least the x-direction and the y-direction. The low-k dielectric 204 reduces the capacitance across the 2D CMG region 202, such as from one of the gates 208 and 210 to an MD layer or an active area layer in another device. The 2D CMG region 202 includes first portions 218 that have a first width W1 and a second portion 220 that has a second width W2 that is greater than the first width W1. The second portion 220 cuts the gates 208 and 210 to provide the shortened gate ends 214 and 216, respectively.

FIG. 12 is a diagram schematically illustrating a table 230 of the geometry of the semiconductor device 200 of FIG. 11, in accordance with some embodiments.

Row A 232 of the table 230 is the CMG width W1 of the first portions 218, which in some embodiments is in a range from 15 to 20 nanometers (nm). Row B 234 of the table 230 is the CMG jog that is the width W2 minus the width W1, which in some embodiments is in a range from 15 to 30 nm. Row C 236 of the table 230 is the CMG region to active area layer spacing, which in some embodiments is in a range from 10 to 15 nm. Row D 238 of the table 230 is the width of the low-k dielectric 204, which in some embodiments is in a range from 15 to 30 nm. Also, in some embodiments, the value in row B 234 is the same as the value in row D 238.

Row E 240 of the table 230 is the distance from the edge of the CMG region 202 to the edge of the low-k dielectric 204, which in some embodiments is in a range from 7.5 to 10 nm. Row F 242 of the table 230 is the maximum active area layer 212 width, which in some embodiments is in a range from 50 to 70 nm. In some embodiments, the value in row E 240 is the same as the value in row A 232 divided by 2.

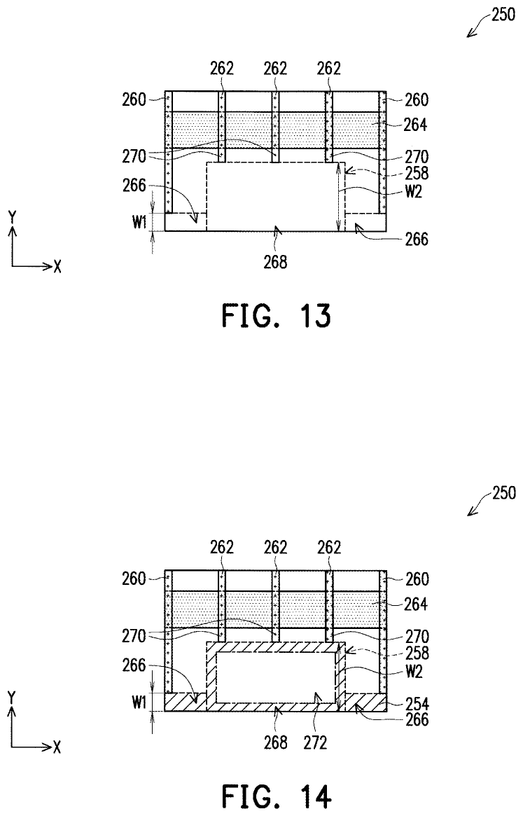

FIGS. 13-15 are diagrams schematically illustrating a semiconductor device 250 and a process for manufacturing a 2D CMG region 252 that includes a high-k dielectric 254 and a low-k dielectric 256 in the semiconductor device 250, in accordance with some embodiments. In some embodiments, the semiconductor device 250 is a CFET that includes two active area layers, one type of active area layer/transistor situated in the z-direction, above another type of active area layer/transistor. In some embodiments, the semiconductor device 250 is like the semiconductor device 20 of FIG. 1. In some embodiments, the semiconductor device 250 is like the semiconductor device 50 of FIG. 3. In some embodiments, the semiconductor device 250 is like the semiconductor device 70 of FIG. 5. In some embodiments, the semiconductor device 250 is like the semiconductor device 150 of FIG. 9. In some embodiments, the semiconductor device 250 is like the semiconductor device 200 of FIG. 11.

FIG. 13 is a diagram schematically illustrating the semiconductor device 250 with a CMG region pattern 258 etched into the semiconductor device 250, in accordance with some embodiments. The semiconductor device 250 includes gates 260 and 262, an active area layer 264, and one or more MD layers (not shown). The active area layer 264 extends in the x-direction and the gates 260 and 262 extend in the y-direction that is perpendicular to the x-direction. The gates 260 and 262 include metal gate material that is removed by etching the CMG region pattern 258 into the semiconductor device 250, i.e., at least some of the metal gate material is removed by etching the CMG region pattern 258 into the semiconductor device 250.

The CMG region pattern 258 includes first portions 266 having a first width W1 and a second portion 268 having a second width W2 that is greater than the first width W1. The first portions 266 of the CMG region pattern 258 extend in the z-direction and cut the gates 260. The second portion 268 of the CMG region pattern 258 extends in the z-direction and cuts the gates 262 to provide the shortened gate ends 270, which results in smaller MD layer to gate end capacitances and smaller active area layer to gate end capacitances, within the semiconductor device 250 and from one semiconductor device, such as the semiconductor device 250, to another semiconductor device.

FIG. 14 is a diagram schematically illustrating filling the CMG region pattern 258 with the high-k dielectric 254, in accordance with some embodiments. The CMG region pattern 258 is partially filled with the high-k dielectric 254, leaving a space 272 that is indicated by arrows for the low-k dielectric 256.

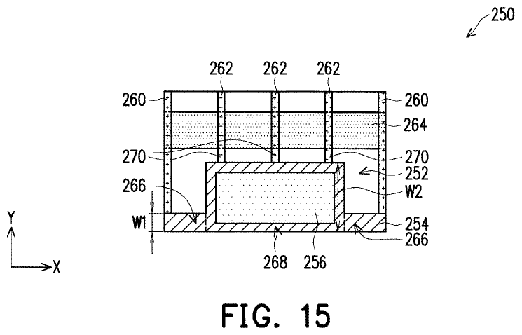

FIG. 15 is a diagram schematically illustrating filling the space 272 with the low-k dielectric 256, in accordance with some embodiments. The 2D CMG region 252 includes the low-k dielectric 256 and the high-k dielectric 254 that surrounds the low-k dielectric 256 in at least the x-direction and the y-direction. The second portion 268 of the CMG region pattern 258 includes the low-k dielectric 256 and cuts the gates 262 to provide the shortened gate ends 270. The low-k dielectric 256 reduces the capacitance across the 2D CMG region 252, such as from one of the gates 262 to an MD layer or an active area layer in another device.

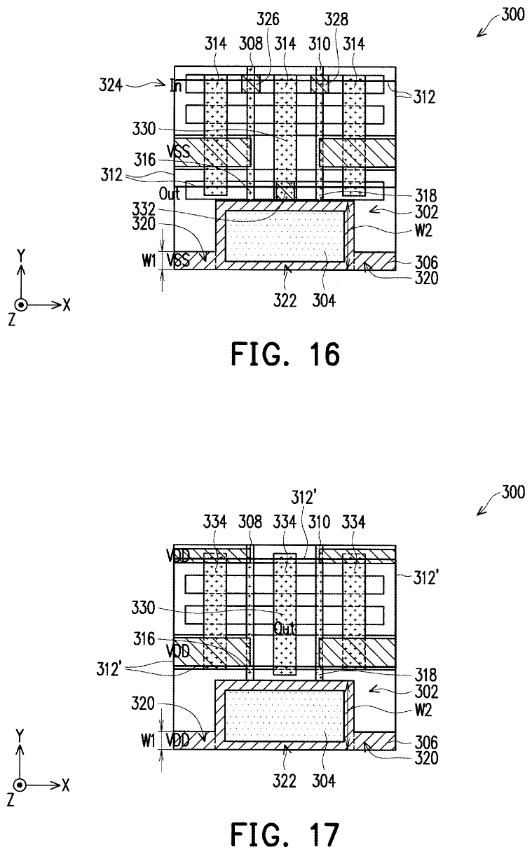

FIGS. 16 and 17 are diagrams schematically illustrating a semiconductor device 300 that includes a 2D CMG region 302, in accordance with some embodiments. The 2D CMG region 302 includes a low-k dielectric 304 and a high-k dielectric 306. The semiconductor device 300 includes n-type transistors situated in the z-direction above p-type transistors. The semiconductor device 300 is connected as a CFET inverter having a driver strength of 2. In some embodiments, the semiconductor device 300 is like the semiconductor device 20 of FIG. 1. In some embodiments, the semiconductor device 300 is like the semiconductor device 50 of FIG. 3. In some embodiments, the semiconductor device 300 is like the semiconductor device 70 of FIG. 5. In some embodiments, the semiconductor device 300 is like the semiconductor device 150 of FIG. 9. In some embodiments, the semiconductor device 300 is like the semiconductor device 200 of FIG. 11.

FIG. 16 is a diagram schematically illustrating the n-type transistors from the front-side of the semiconductor device 300, in accordance with some embodiments. The semiconductor device 300 includes the 2D CMG region 302, gates 308 and 310, an n-type active area layer 312, and MD layers 314. The n-type active area layer 312 extends in the x-direction and the gates 308 and 310 and the MD layers 314 extend in the y-direction that is perpendicular to the x-direction.

The 2D CMG region 302 extends in the z-direction and cuts the gates 308 and 310 to provide the shortened gate ends 316 and 318, respectively, which results in smaller MD layer to gate end capacitances and smaller active area layer to gate end capacitances.

The 2D CMG region 302 includes the low-k dielectric 304 and the high-k dielectric 306 that surrounds the low-k dielectric 304 in at least the x-direction and the y-direction. The low-k dielectric 304 reduces the capacitance across the 2D CMG region 302, such as from one of the gates 308 and 310 to an MD layer or an active area layer in another device. The 2D CMG region 302 includes first portions 320 that have a first width W1 and a second portion 322 that has a second width W2 that is greater than the first width W1. The second portion 322 cuts the gates 308 and 310 to provide the shortened gate ends 316 and 318, respectively.

The semiconductor device 300 is connected as a CFET inverter having a driver strength of 2. The gates 308 and 310 are connected to an input 324 by vias 326 and 328, respectively. A reference voltage VSS is connected to the MD layers 314 over the n-type active area layer 312 on one side of each of the gates 308 and 310. The other side of each the gates 308 and 310 is connected to an output OUT through a contact 330 and a via 332. In some embodiments, the high-k dielectric 306 is connected to the reference voltage VSS.

FIG. 17 is a diagram schematically illustrating the p-type transistors from the back-side of the semiconductor device 300, in accordance with some embodiments. The semiconductor device 300 includes the 2D CMG region 302, the gates 308 and 310, a p-type active area layer 312′, and MD layers 334. The p-type active area layer 312′ extends in the x-direction and the gates 308 and 310 and the MD layers 334 extend in the y-direction that is perpendicular to the x-direction.

The 2D CMG region 302 extends in the z-direction and cuts the gates 308 and 310 to provide the shortened gate ends 316 and 318, respectively. Also, the 2D CMG region 302 includes the low-k dielectric 304 and the high-k dielectric 306 that surrounds the low-k dielectric 304, and the 2D CMG region 302 includes the first portions 320 that have the first width W1 and the second portion 322 that has the second width W2 that is greater than the first width W1, where the second portion 322 cuts the gates 308 and 310 to provide the shortened gate ends 316 and 318, respectively.

The semiconductor device 300 is connected as the CFET inverter having a driver strength of 2. A power voltage VDD is connected to the MD layers 334 over the p-type active area layer 312′ on one side of each of the gates 308 and 310. The other side of each the gates 308 and 310 is connected to the output OUT through contact 330. In some embodiments, the high-k dielectric 306 is connected to the power voltage VDD.

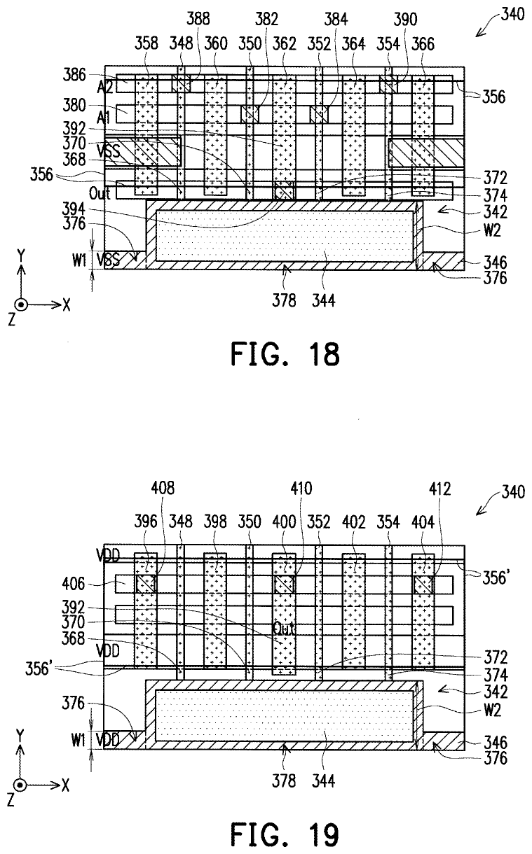

FIGS. 18 and 19 are diagrams schematically illustrating a semiconductor device 340 that is a 2-input NAND gate that includes a 2D CMG region 342, in accordance with some embodiments. The 2D CMG region 342 includes a low-k dielectric 344 and a high-k dielectric 346. The semiconductor device 340 includes n-type transistors situated in the z-direction above p-type transistors. The semiconductor device 340 is connected as a 2-input NAND gate having a driver strength of 2. In some embodiments, the semiconductor device 340 is connected as a 2-input NAND gate having a driver strength of 4. In some embodiments, the semiconductor device 340 is like the semiconductor device 20 of FIG. 1. In some embodiments, the semiconductor device 340 is like the semiconductor device 50 of FIG. 3. In some embodiments, the semiconductor device 340 is like the semiconductor device 70 of FIG. 5. In some embodiments, the semiconductor device 340 is like the semiconductor device 150 of FIG. 9. In some embodiments, the semiconductor device 340 is like the semiconductor device 200 of FIG. 11.

FIG. 18 is a diagram schematically illustrating the n-type transistors from the front-side of the semiconductor device 340 connected as a 2-input NAND gate, in accordance with some embodiments. The semiconductor device 340 includes the 2D CMG region 342, gates 348, 350, 352, and 354, an n-type active area layer 356, and MD layers 358, 360, 362, 364, and 366. The n-type active area layer 356 extends in the x-direction and the gates 348, 350, 352, and 354 and MD layers 358, 360, 362, 364, and 366 extend in the y-direction that is perpendicular to the x-direction.

The 2D CMG region 342 extends in the z-direction and cuts the gates 348, 350, 352, and 354 to provide the shortened gate ends 368, 370, 372, and 374, respectively, which results in smaller MD layer to gate end capacitances and smaller active area layer to gate end capacitances.

The 2D CMG region 342 includes the low-k dielectric 344 and the high-k dielectric 346 that surrounds the low-k dielectric 344 in at least the x-direction and the y-direction. The low-k dielectric 344 reduces the capacitance across the 2D CMG region 342, such as from one of the gates 348, 350, 352, and 354 to an MD layer or an active area layer in another device. The 2D CMG region 342 includes first portions 376 that have a first width W1 and a second portion 378 that has a second width W2 that is greater than the first width W1. The second portion 378 cuts the gates 348, 350, 352, and 354 to provide the shortened gate ends 368, 370, 372, and 374, respectively.

The semiconductor device 340 is connected as a 2-input NAND gate having a driver strength of 2. The gates 350 and 352 are connected to an input A1 380 by vias 382 and 384, respectively. The gates 348 and 354 are connected to an input A2 386 by vias 388 and 390, respectively. A reference voltage VSS is connected to the MD layers 358 and 366 over the n-type active area layer 356 on one side of each of the gates 348 and 354. The other side of each the gates 348 and 354 is connected to one side of the gates 350 and 352, and the other side of the gates 350 and 352 is connected to an output OUT through a contact 392 and a via 394. In some embodiments, the high-k dielectric 346 is connected to the reference voltage VSS.

FIG. 19 is a diagram schematically illustrating the p-type transistors from the back-side of the semiconductor device 340 that is connected as a 2-input NAND gate, in accordance with some embodiments. The semiconductor device 340 includes the 2D CMG region 342, the gates 348, 350, 352, and 354, a p-type active area layer 356′, and MD layers 396, 398, 400, 402, and 404. The p-type active area layer 356′ extends in the x-direction and the gates 348, 350, 352, and 354 and the MD layers 396, 398, 400, 402, and 404 extend in the y-direction that is perpendicular to the x-direction.

The 2D CMG region 342 extends in the z-direction and cuts the gates 348, 350, 352, and 354 to provide the shortened gate ends 368, 370, 372, and 374, respectively. Also, the 2D CMG region 342 includes the low-k dielectric 344 and the high-k dielectric 346 that surrounds the low-k dielectric 344, and the 2D CMG region 342 includes the first portions 376 that have the first width W1 and the second portion 378 that has the second width W2 that is greater than the first width W1. The second portion 378 cuts the gates 348, 350, 352, and 354 to provide the shortened gate ends 368, 370, 372, and 374, respectively.

The semiconductor device 340 is connected as a 2-input NAND gate having a driver strength of 2. A power voltage VDD is connected to the MD layers 398 and 402 over the p-type active area layer 356′ and on one side of each of the gates 348, 350, 352, and 354. The other side of each the gates 348, 350, 352, and 354 is connected to the output OUT through metal layer 406, vias 408, 410, and 412, and contact 392. In some embodiments, the high-k dielectric 346 is connected to the power voltage VDD.

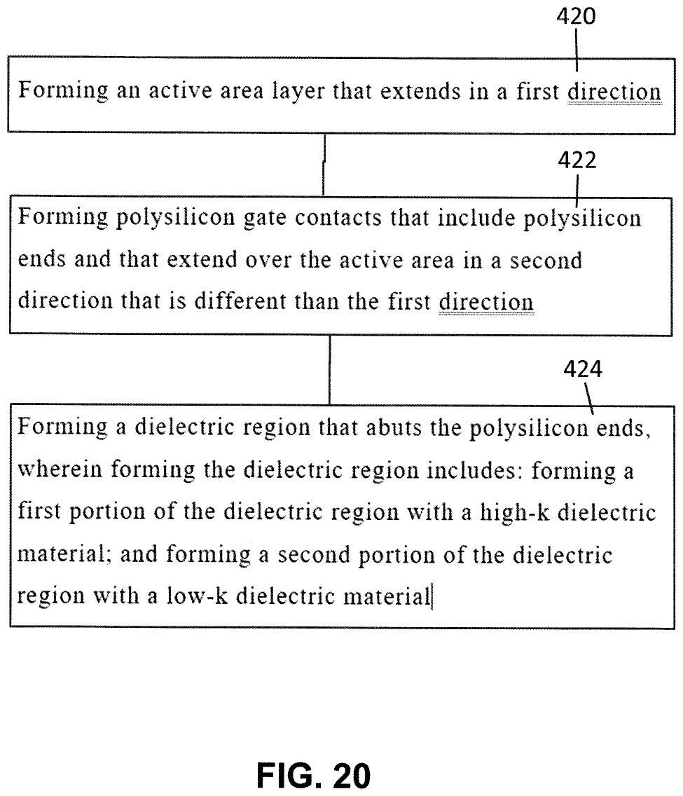

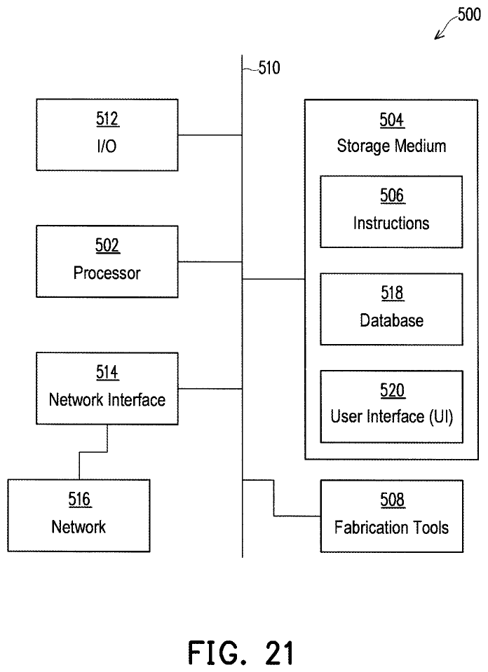

FIG. 20 is a diagram schematically illustrating a method of manufacturing a semiconductor device, such as the semiconductor device 250 of FIGS. 13-15, in accordance with some embodiments. At 420, the method includes forming an active area layer, such as the active area layer 264, that extends in a first direction, such as the x-direction. At 422, the method includes forming gates that include gate ends and that extend over the active area in a second direction that is different than the first direction. At 424, the method includes forming a dielectric region that abuts the gate ends, wherein forming the dielectric region includes: forming a first portion of the dielectric region with a high-k dielectric material; and forming a second portion of the dielectric region with a low-k dielectric material. In some embodiments, the second portion is situated inside the first portion of the dielectric region. In some embodiments, the method includes forming gates that include metal gate material, removing at least some of the metal gate material from at least one of the gates to form a CMG region, such as the CMG region pattern 258, filling a first portion of the CMG region with a high-k dielectric material, such as the high-k dielectric 254, and filling a second portion, such as the space 272, of the CMG region with a low-k dielectric material, such as the low-k dielectric 256. In some embodiments, the second portion is situated inside the first portion of the CMG region.

In some embodiments, the method includes forming an MD layer that extends in the second direction, such as the y-direction. The MD layer is situated over the active area layer. Also, in some embodiments, the method includes wherein the second direction, such as the y-direction, is perpendicular to the first direction, such as the x-direction.

FIG. 21 is a block diagram schematically illustrating an example of a computer system 500 configured to provide the semiconductor devices and methods of the current disclosure, in accordance with some embodiments. Some or all the design, layout, and manufacture of the semiconductor devices, also referred to as semiconductor circuits, can be performed by or with the computer system 500. In some embodiments, the computer system 500 includes an electronic design automation (EDA) system. In some embodiments, the semiconductor devices are ICs.

In some embodiments, the system 500 is a general-purpose computing device including a processor 502 and a non-transitory, computer-readable storage medium 504. The computer-readable storage medium 504 may be encoded with, e.g., store, computer program code such as executable instructions 506. Execution of the instructions 506 by the processor 502 provides (at least in part) a design tool that implements a portion or all the functions of the system 500, such as pre-layout simulations, post-layout simulations, routing, rerouting, and final layout for manufacturing. Further, fabrication tools 508 are included to further layout and physically implement the design and manufacture of the semiconductor devices. In some embodiments, execution of the instructions 506 by the processor 502 provides (at least in part) a design tool that implements a portion or all the functions of the system 500. In some embodiments, the system 500 includes a commercial router. In some embodiments, the system 500 includes an automatic place and route (APR) system.

The processor 502 is electrically coupled to the computer-readable storage medium 504 by a bus 510 and to an I/O interface 512 by the bus 510. A network interface 514 is also electrically connected to the processor 502 by the bus 510. The network interface 514 is connected to a network 516, so that the processor 502 and the computer-readable storage medium 504 can connect to external elements using the network 516. The processor 502 is configured to execute the computer program code or instructions 506 encoded in the computer-readable storage medium 504 to cause the system 500 to perform a portion or all the functions of the system 500, such as providing the semiconductor devices and methods of the current disclosure and other functions of the system 500. In some embodiments, the processor 502 is a central processing unit (CPU), a multi-processor, a distributed processing system, an application specific integrated circuit (ASIC), and/or a suitable processing unit.

In some embodiments, the computer-readable storage medium 504 is an electronic, magnetic, optical, electromagnetic, infrared, and/or semiconductor system or apparatus or device. For example, the computer-readable storage medium 504 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 504 can include a compact disk read only memory (CD-ROM), a compact disk read/write memory (CD-R/W), and/or a digital video disc (DVD).

In some embodiments, the computer-readable storage medium 504 stores computer program code or instructions 506 configured to cause the system 500 to perform a portion or all the functions of the system 500. In some embodiments, the computer-readable storage medium 504 also stores information which facilitates performing a portion or all the functions of the system 500. In some embodiments, the computer-readable storage medium 504 stores a database 518 that includes one or more of component libraries, digital circuit cell libraries, and databases.

The system 500 includes the I/O interface 512, which is coupled to external circuitry. In some embodiments, the I/O interface 512 includes a keyboard, keypad, mouse, trackball, trackpad, touchscreen, and/or cursor direction keys for communicating information and commands to the processor 502.

The network interface 514 is coupled to the processor 502 and allows the system 500 to communicate with the network 516, to which one or more other computer systems are connected. The network interface 514 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 500 can be performed in two or more systems that are like system 500.

The system 500 is configured to receive information through the I/O interface 512. The information received through the I/O interface 512 includes one or more of instructions, data, design rules, libraries of components and cells, and/or other parameters for processing by the processor 502. The information is transferred to the processor 502 by the bus 510. Also, the system 500 is configured to receive information related to a user interface (UI) through the I/O interface 512. This UI information can be stored in the computer-readable storage medium 504 as a UI 520.

In some embodiments, a portion or all the functions of the system 500 are implemented via a standalone software application for execution by a processor. In some embodiments, a portion or all the functions of the system 500 are implemented in a software application that is a part of an additional software application. In some embodiments, a portion or all the functions of the system 500 are implemented as a plug-in to a software application. In some embodiments, at least one of the functions of the system 500 is implemented as a software application that is a portion of an EDA tool. In some embodiments, a portion or all the functions of the system 500 are implemented as a software application that is used by the system 500. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 500 include fabrication tools 508 for implementing the manufacturing processes of the system 500. For example, based on the final layout, photolithographic masks may be generated, which are used to fabricate the semiconductor device by the fabrication tools 508.

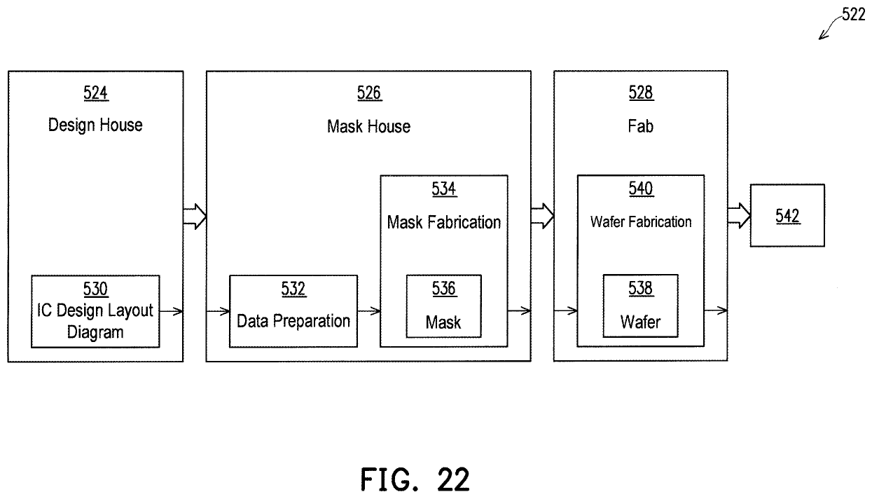

Further aspects of device fabrication are disclosed in conjunction with FIG. 22, which is a block diagram of a semiconductor device manufacturing system 522 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 522.

In FIG. 22, the semiconductor device manufacturing system 522 includes entities, such as a design house 524, a mask house 526, and a semiconductor device manufacturer/fabricator (“Fab”) 528, that interact with one another in the design, development, and manufacturing cycles and/or services related to manufacturing a semiconductor device, such as the semiconductor devices described herein. The entities in the system 522 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 524, the mask house 526, and the semiconductor device fab 528 are owned by a single larger company. In some embodiments, two or more of the design house 524, the mask house 526, and the semiconductor device fab 528 coexist in a common facility and use common resources.

The design house (or design team) 524 generates a semiconductor device design layout diagram 530. The semiconductor device design layout diagram 530 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 530 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 524 implements a design procedure to form a semiconductor device design layout diagram 530. The semiconductor device design layout diagram 530 is presented in one or more data files having information of the geometrical patterns. For example, semiconductor device design layout diagram 530 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 526 includes data preparation 532 and mask fabrication 534. The mask house 526 uses the semiconductor device design layout diagram 530 to manufacture one or more masks 536 to be used for fabricating the various layers of the semiconductor device or semiconductor structure. The mask house 526 performs mask data preparation 532, where the semiconductor device design layout diagram 530 is translated into a representative data file (RDF). The mask data preparation 532 provides the RDF to the mask fabrication 534. The mask fabrication 534 includes a mask writer that converts the RDF to an image on a substrate, such as a mask (reticle) 536 or a semiconductor wafer 538. The design layout diagram 530 is manipulated by the mask data preparation 532 to comply with characteristics of the mask writer and/or criteria of the semiconductor device fab 528. In FIG. 22, the mask data preparation 532 and the mask fabrication 534 are illustrated as separate elements. In some embodiments, the mask data preparation 532 and the mask fabrication 534 can be collectively referred to as mask data preparation.

In some embodiments, the mask data preparation 532 includes an optical proximity correction (OPC) which uses lithography enhancement techniques to compensate for image errors, such as those that can arise from diffraction, interference, other process effects and the like. The OPC adjusts the semiconductor device design layout diagram 530. In some embodiments, the mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 532 includes a mask rule checker (MRC) that checks the semiconductor device design layout diagram 530 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 530 to compensate for limitations during the mask fabrication 534, which may undo part of the modifications performed by OPC to meet mask creation rules.

In some embodiments, the mask data preparation 532 includes lithography process checking (LPC) that simulates processing that will be implemented by the semiconductor device fab 528. LPC simulates this processing based on the semiconductor device design layout diagram 530 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 530.

The above description of mask data preparation 532 has been simplified for the purposes of clarity. In some embodiments, data preparation 532 includes additional features such as a logic operation (LOP) to modify the semiconductor device design layout diagram 530 according to manufacturing rules. Additionally, the processes applied to the semiconductor device design layout diagram 530 during data preparation 532 may be executed in a variety of different orders.

After the mask data preparation 532 and during the mask fabrication 534, a mask 536 or a group of masks 536 are fabricated based on the modified semiconductor device design layout diagram 530. In some embodiments, the mask fabrication 534 includes performing one or more lithographic exposures based on the semiconductor device design layout diagram 530. In some embodiments, an electron-beam (e-beam) or a mechanism of multiple e-beams is used to form a pattern on a mask (photomask or reticle) 536 based on the modified semiconductor device design layout diagram 530. The mask 536 can be formed in various technologies. In some embodiments, the mask 536 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 536 includes a transparent substrate (e.g., fused quartz) and an opaque material (e.g., chromium) coated in the opaque regions of the binary mask. In another example, the mask 536 is formed using a phase shift technology. In a phase shift mask (PSM) version of the mask 536, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 534 is used in a variety of processes. For example, such a mask(s) is used in an ion implantation process to form various doped regions in the semiconductor wafer 538, in an etching process to form various etching regions in the semiconductor wafer 538, and/or in other suitable processes.

The semiconductor device fab 528 includes wafer fabrication 540. The semiconductor device fab 528 is a semiconductor device fabrication business that includes one or more manufacturing facilities for the fabrication of a variety of different semiconductor device products. In some embodiments, the semiconductor device fab 528 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 528 uses the mask(s) 536 fabricated by the mask house 526 to fabricate the semiconductor structures or semiconductor devices 542 of the current disclosure. Thus, the semiconductor device fab 528 at least indirectly uses the semiconductor device design layout diagram 530 to fabricate the semiconductor structures or semiconductor devices 542 of the current disclosure. Also, the semiconductor wafer 538 includes a silicon substrate or other proper substrate having material layers formed thereon, and the semiconductor wafer 538 further includes one or more of various doped regions, dielectric features, multilevel interconnects, and the like (formed at subsequent manufacturing steps). In some embodiments, the semiconductor wafer 538 is fabricated by the semiconductor device fab 528 using the mask(s) 536 to form the semiconductor structures or semiconductor devices 542 of the current disclosure. In some embodiments, the semiconductor device fabrication includes performing one or more lithographic exposures based at least indirectly on the semiconductor device design layout diagram 530.

Disclosed embodiments provide semiconductor devices that have shortened and/or minimum length gate ends that extend from an edge of an active area layer to an edge of a CMG region of the semiconductor device. The shorter gate ends reduce the gate end capacitance, such as the capacitance from the gate to an MD layer or the capacitance from the gate to an active area layer. In some embodiments, the capacitance is from a gate in one cell to an MD layer in the same cell. In some embodiments, the capacitance is from a gate in one cell to an MD layer in another cell. In some embodiments, the capacitance is from a gate in one cell to an active area layer in another cell.

Also, disclosed embodiments provide a semiconductor device that includes a gate and a CMG region that cuts the gate to provide a shortened gate end, i.e., a shortened gate end. The CMG region includes a first portion having a first width and a second portion having a second width that is greater than the first width. The second portion cuts the gate to provide the shortened gate end. The second portion includes a high-k dielectric material situated around a low-k dielectric in at least the x-direction and the y-direction. In some embodiments, the shortened gate end is a minimum length gate end.

In accordance with some embodiments, a semiconductor device includes a first active area layer that extends in a first direction, a first metal over diffusion layer that extends in a second direction that is different than the first direction, the first metal over diffusion layer situated over the first active area layer, a first gate that extends in the second direction and over the first active area layer, a first gate end of the first gate that abuts a first dielectric region, and first low-k dielectric material situated in the first dielectric region.

In accordance with further embodiments, a semiconductor device includes a first cell and a second cell. The first cell includes a first active area layer that extends in a first direction, a first metal over diffusion layer that extends in a second direction that is perpendicular to the first direction, the first metal over diffusion layer situated over the first active area layer, a first gate that extends in the second direction and over the first active area layer, and a first gate end of the first gate that abuts a first dielectric region. The second cell includes a second active area layer that extends in the first direction, a second metal over diffusion layer that extends in the second direction over the second active area layer, a second gate that extends in the second direction and over the second active area layer, a second gate end of the second gate that abuts a second dielectric region, and a third gate end of the second gate in the second cell that abuts the first dielectric region.

In accordance with still further disclosed aspects, a method of manufacturing a semiconductor device includes forming an active area layer that extends in a first direction, forming gates that include gate ends and that extend over the active area in a second direction that is different than the first direction, and forming a dielectric region that abuts the gate ends, wherein forming the dielectric region includes: forming a first portion of the dielectric region with a high-k dielectric material, and forming a second portion of the dielectric region with a low-k dielectric material.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first active area layer that extends in a first direction;
a first metal over diffusion layer that extends in a second direction that is different than the first direction, the first metal over diffusion layer situated over the first active area layer;
a first gate that extends in the second direction and over the first active area layer;
a first gate end of the first gate that abuts a first dielectric region; and
first low-k dielectric material situated in the first dielectric region.

2. The device of claim 1, wherein the first dielectric region does not include the first gate.

3. The device of claim 1, wherein the first direction is perpendicular to the second direction.

4. The device of claim 1, wherein the first dielectric region includes a first portion having a first width and a second portion having a second width that is greater than the first width.

5. The device of claim 4, wherein the second portion abuts the first gate at the first gate end.

6. The device of claim 4, wherein the first low-k dielectric material is situated in the second portion of the first dielectric region.

7. The device of claim 1, comprising an insulation layer situated under the first active area layer and above a second active area layer that extends in the first direction.

8. The device of claim 7, comprising a second metal over diffusion layer that extends in the second direction and under the second active area layer.

9. The device of claim 8, wherein the first gate extends over the second active area layer and abuts the first dielectric region.

10. The device of claim 1, comprising:
a second active area layer that extends in the first direction, the second active area layer separated from the first active area layer in the second direction;
a second metal over diffusion layer that extends in the second direction over the second active area layer;
a second gate that extends in the second direction and over the second active area layer;
a second gate end of the second gate that abuts a second dielectric region; and
second low-k dielectric material situated in the second dielectric region.

11. A semiconductor device, comprising:
a first cell including:
a first active area layer that extends in a first direction;
a first metal over diffusion layer that extends in a second direction that is perpendicular to the first direction, the first metal over diffusion layer situated over the first active area layer;
a first gate that extends in the second direction and over the first active area layer; and
a first gate end of the first gate that abuts a first dielectric region; and
a second cell including:
a second active area layer that extends in the first direction;
a second metal over diffusion layer that extends in the second direction over the second active area layer;
a second gate the that extends in the second direction and over the second active area layer;
a second gate end of the second gate that abuts a second dielectric region; and
a third gate end of the second gate in the second cell that abuts the first dielectric region.

12. The device of claim 11, wherein the first dielectric region includes a first portion having a first width and a second portion having a second width that is greater than the first width and that extends into the first cell and the second cell.

13. The device of claim 12, wherein the second portion abuts the first gate the in the first cell at the first gate end and the second gate the in the second cell at the third gate end.

14. The device of claim 12, wherein a low-k dielectric is situated in the second portion.

15. The device of claim 11, comprising an insulation layer situated under the first active area layer and above a third active area layer that extends in the first direction.

16. The device of claim 15, comprising a third metal over diffusion layer that extends in the second direction and under the third active area layer, wherein the first gate extends over the third active area layer and the first dielectric region abuts the first gate.

17. A method of manufacturing a semiconductor device, the method comprising:
forming an active area layer that extends in a first direction;
forming gates that include gate ends and that extend over the active area in a second direction that is different than the first direction; and
forming a dielectric region that abuts the gate ends, wherein forming the dielectric region includes:
forming a first portion of the dielectric region with a high-k dielectric material; and
forming a second portion of the dielectric region with a low-k dielectric material.

18. The method of claim 17, wherein the second portion is situated inside the first portion of the dielectric region.

19. The method of claim 17, comprising forming a metal over diffusion layer that extends in the second direction, the metal over diffusion layer situated over the active area layer.

20. The method of claim 17, wherein the second direction is perpendicular to the first direction.
